(19) United States
(12) Patent Application Publication
(10) Pub. No.: US 2025/0259839 A1
(43) Pub. Date: Aug. 14, 2025

(54) METHOD FOR PRODUCING THIN FILM, THIN FILM, AND SUBSTRATE PROCESSING APPARATUS

(71) Applicant: JUSUNG ENGINEERING CO., LTD., Gwangju-si, Gyeonggi-do (KR)

(72) Inventors: Jae Wuk SO, Yongin-si, Gyeonggi-do (KR); Se Whan JIN, Yongin-si, Gyeonggi-do (KR); Jeong Uk EOM, Yongin-si, Gyeonggi-do (KR); Min Jin SONG, Yongin-si, Gyeonggi-do (KR); Chul Joo HWANG, Yongin-si, Gyeonggi-do (KR)

(21) Appl. No.: 18/992,564

(22) PCT Filed: Jul. 11, 2023
(86) PCT No.: PCT/KR2023/009808

§ 371 Date: Jan. 8, 2025

(30) Foreign Application Priority Data
Jul. 22, 2022 (KR) 10-2022-0090933

(51) Int. Cl. H01L 21/02

(52) U.S. Cl. CPC H01L 21/0234; H01L 21/0206; H01L 21/02181; H01L 21/02189

(57) ABSTRACT

The present inventive concept relates to: a method for producing a thin film, the method comprising a first forming step for forming a first thin film layer on a substrate by spraying a first source gas comprising a high dielectric constant (High-k) material, a second forming step for forming a second thin film layer on the substrate by spraying a second source gas comprising a high dielectric constant material, and a crystallization step for crystallizing at least one among the first thin film layer and the second thin film layer by using plasma; a thin film; and a substrate processing apparatus.

### TECHNICAL FIELD

The present inventive concept relates to a method of manufacturing a thin film on a substrate through a processing process such as a deposition process on the substrate, a thin film, and a substrate processing apparatus.

### BACKGROUND ART

Generally, a thin film layer, a thin film circuit pattern, or an optical pattern should be formed on a substrate for manufacturing a semiconductor device, a display device, a solar cell, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Through such a processing process on a substrate, a thin film may be manufactured on the substrate.

Recently, a semiconductor device, a display device, and a solar cell have been more miniaturized and have also been developed to have a thinner thickness, and to this end, a thickness of a thin film should be thinned. However, in a thin film which is implemented as an insulation layer between a semiconductor layer and a gate layer in a thin film transistor (TFT), there is a problem where the leakage of a current occurs due to a tunneling phenomenon as a thickness of the thin film is thinned.

Therefore, it is required to develop a thin film for reducing the leakage of a current despite that a thickness of the thin film is implemented to be thin.

### DISCLOSURE

### Technical Problem

The present inventive concept is devised to solve the above-described problem and is for providing a method of manufacturing a thin film and a thin film, which may reduce the leakage of a current despite having a thin thickness.

### Technical Solution

To accomplish the above-described objects, the present inventive concept may include the following elements.

A method of manufacturing a thin film, according to the present inventive concept, may include: a first formation step of injecting a first source gas including a high-k dielectric material to form a first thin film layer on a substrate; a second formation step of injecting a second source gas including a high-k dielectric material to form a second thin film layer on the substrate; and a crystallization step of crystallizing at least one of the first thin film layer and the second thin film layer by using plasma.

A thin film according to the present inventive concept may include: a first thin film layer formed on a substrate by using a high-k dielectric material and crystallized by plasma; and a second thin film layer formed on the substrate by using a high-k dielectric material.

A substrate processing apparatus according to the present inventive concept may include: a chamber; a substrate supporting unit supporting a substrate in the chamber; an upper dome provided on an upper surface of the chamber; and an antenna disposed over the upper dome to generate inductively-coupled plasma, wherein the upper dome may be formed of ceramic.

### Advantageous Effect

According to the present inventive concept, the following effects may be realized.

The present inventive concept may be implemented so that all of a first thin film layer and a second thin film layer are formed of a high-k dielectric material and at least one of the first thin film layer and the second thin film layer is crystallized, and thus, may more decrease the leakage of a current despite being formed to have a thinner thickness. Accordingly, the present inventive concept may manufacture a thin film transistor and the like, which are finer and have a thinner thickness, and may more decrease the leakage of a current, thereby contributing to more enhancing the performance of a thin film transistor and the like.

### DESCRIPTION OF DRAWINGS

FIG. 1 is a schematic block diagram illustrating an embodiment of a substrate processing apparatus which performs a method of manufacturing a thin film according to the present inventive concept.

FIG. 2 is a schematic side cross-sectional view of an injection unit injecting a gas in an example of a substrate processing apparatus which performs a method of manufacturing a thin film according to the present inventive concept.

FIG. 3 is a schematic side cross-sectional view illustrating an example of a thin film transistor.

FIG. 4 is a schematic flowchart of a method of manufacturing a thin film according to the present inventive concept.

FIG. 5 is a schematic side cross-sectional view of a thin film manufactured through a method of manufacturing a thin film according to the present inventive concept.

FIG. 6 is a schematic flowchart of an embodiment including a removal step in a method of manufacturing a thin film according to the present inventive concept.

FIGS. 7 and 8 are schematic flowcharts of a first formation step and a first crystallization step in a method of manufacturing a thin film according to the present inventive concept.

FIGS. 9 and 10 are schematic flowcharts of a second formation step and a second crystallization step in a method of manufacturing a thin film according to the present inventive concept.

FIG. 11 is a schematic side cross-sectional view of an embodiment where only a first thin film layer is crystallized in a thin film manufactured through a method of manufacturing a thin film according to the present inventive concept.

FIG. 12 is a schematic side cross-sectional view of an embodiment where only a second thin film layer is crystallized in a thin film manufactured through a method of manufacturing a thin film according to the present inventive concept.

FIG. 13 is a schematic flowchart of an embodiment including a third formation step in a method of manufacturing a thin film according to the present inventive concept.

FIG. 14 is a schematic side cross-sectional view of an embodiment where a thin film manufactured through a method of manufacturing a thin film according to the present inventive concept includes a first thin film layer, a second thin film layer, and a third thin film layer.

FIG. 15 is a schematic block diagram illustrating another embodiment of a substrate processing apparatus which performs a method of manufacturing a thin film according to the present inventive concept.

### MODE FOR INVENTIVE CONCEPT

Hereinafter, an embodiment of a method of manufacturing a thin film according to the present inventive concept will be described in detail with reference to the accompanying drawings. In describing an embodiment of the present inventive concept, when an arbitrary structure is described as being formed “on” or “under” another structure, this description should be construed as including a case, where a third structure is disposed between the structures, as well as a case where the structures contact each other.

Referring to FIGS. 1 to 4, the method of manufacturing a thin film according to the present inventive concept performs a processing process on a substrate S to manufacture a thin film on the substrate S. The substrate S may be a silicon substrate, a glass substrate, a metal substrate, or the like.

The method of manufacturing a thin film according to the present inventive concept may be performed by a substrate processing apparatus 1. Before describing an embodiment of the method of manufacturing a thin film according to the present inventive concept, the substrate processing apparatus 1 will be described below in detail.

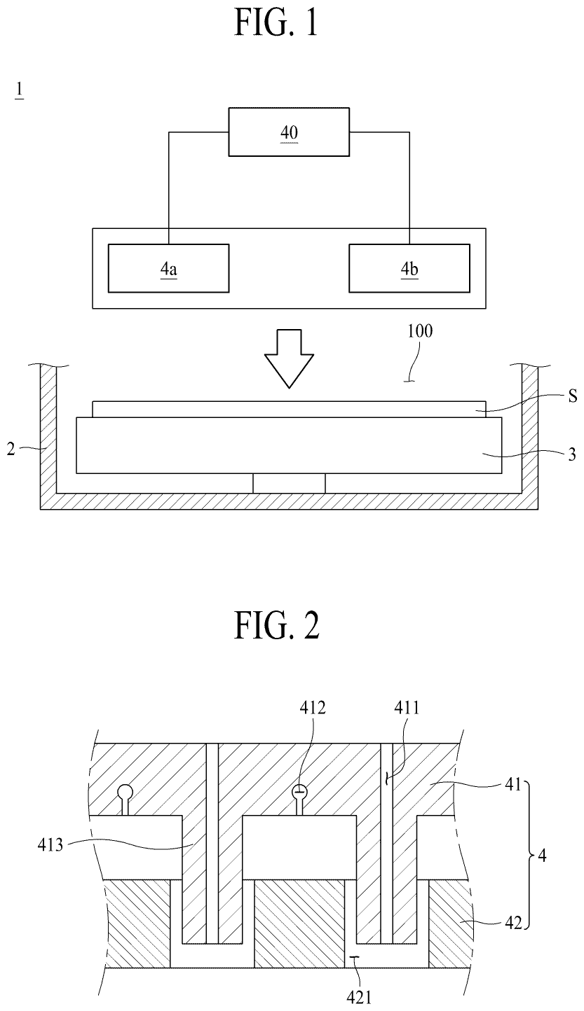

Referring to FIGS. 1 and 2, the substrate processing apparatus 1 may include a chamber 2, a susceptor 3, and an injection unit 4.

The chamber 2 provides a processing space 100. A process of performing a processing process on the substrate S to manufacture a thin film on the substrate S may be performed in the processing space 100. The processing space 100 may be disposed in the chamber 2. An exhaust port (not shown) which exhausts a gas from the processing space 100 may be coupled to the chamber 2. The susceptor 3 and the injection unit 4 may be disposed in the chamber 2.

The susceptor 3 supports the substrate S. The susceptor 3 may support one substrate S, or may support a plurality of substrates S. In a case where the plurality of substrates S are supported by the susceptor 3, a process of performing a processing process on the plurality of substrates S at a time to manufacture a thin film on each of the substrates S may be performed. The susceptor 3 may be coupled to the chamber 2. The susceptor 3 may be disposed in the chamber 2.

The injection unit 4 injects a gas toward the susceptor 3. The injection unit 4 may be connected with a gas storage unit 40. In this case, the injection unit 4 may inject a gas, supplied from the gas storage unit 40, toward the susceptor 3. The injection unit 4 may be disposed in the chamber 2. The injection unit 4 may be disposed to be opposite to the susceptor 3. The injection unit 4 may be disposed over the susceptor 3. The processing space 100 may be disposed between the injection unit 4 and the susceptor 3. The injection unit 4 may be coupled to a lid (not shown). The lid may be coupled to the chamber 2 to cover an upper portion of the chamber 2.

The injection unit 4 may include a first gas flow path 4a and a second gas flow path 4b.

The first gas flow path 4a is for injecting a first gas. One side of the first gas flow path 4a may be connected with the gas storage unit 40 through a pipe, a hose, or the like. The other side of the first gas flow path 4a may communicate with the processing space 100. Accordingly, the first gas supplied from the gas storage unit 40 may flow along the first gas flow path 4a, and then, may be injected into the processing space 100 through the first gas flow path 4a. The first gas flow path 4a may function as a flow path for enabling the first gas to flow and may function as an injection port for injecting the first gas into the processing space 100.

The second gas flow path 4b is for injecting a second gas. The second gas and the first gas may be different gases. For example, when the first gas is a source gas, the second gas may be a reactant gas. One side of the second gas flow path 4b may be connected with the gas storage unit 40 through a pipe, a hose, or the like. The other side of the second gas flow path 4b may communicate with the processing space 100. Accordingly, the second gas supplied from the gas storage unit 40 may flow along the second gas flow path 4b, and then, may be injected into the processing space 100 through the second gas flow path 4b. The second gas flow path 4b may function as a flow path for enabling the second gas to flow and may function as an injection port for injecting the second gas into the processing space 100.

The second gas flow path 4b and the first gas flow path 4a may be disposed to be spatially separated from each other. Therefore, the second gas supplied from the gas storage unit 40 to the second gas flow path 4b may be injected into the processing space 100 without passing through the first gas flow path 4a. The first gas supplied from the gas storage unit 40 to the second gas flow path 4b may be injected into the processing space 100 without passing through the second gas flow path 4b. The second gas flow path 4b and the first gas flow path 4a may inject a gas toward different portions of the processing space 100.

For example, the injection unit 4 may include a first plate 41 and a second plate 42.

The first plate 41 is disposed over the second plate 42. The first plate 41 and the second plate 42 may be disposed apart from each other. A plurality of first gas holes 411 may be formed in the first plate 41. Each of the first gas holes 411 may function as a path for enabling the first gas to flow. The first gas holes 411 may be included in the first gas flow path 4a. A plurality of second gas holes 412 may be formed in the second plate 42. Each of the second gas holes 412 may function as a path for enabling the second gas to flow. The second gas holes 412 may be included in the second gas flow path 4b. A plurality of protrusion members 413 may be coupled to the first plate 41. The protrusion members 413 may protrude toward the second plate 42 from a lower surface of the first plate 41. Each of the first gas holes 411 may be formed to pass through the first plate 41 and the protrusion member 413.

A plurality of openings 421 may be formed in the second plate 42. The openings 421 may be formed to pass through the second plate 42. The openings 421 may be disposed at position respectively corresponding to the protrusion members 413. Therefore, as illustrated in FIG. 2, the protrusion members 413 may be formed by a length which enables the protrusion members 413 to be respectively inserted into the openings 421. Although not shown, the protrusion members 413 may be formed by a length which enables the protrusion members 413 to be respectively disposed over the openings 421. The protrusion members 413 may be formed by a length which protrudes downward from the second plate 42. The second gas holes 412 may be disposed to inject a gas toward an upper surface of the second plate 42.

The injection unit 4 may generate plasma by using the second plate 42 and the first plate 41. In this case, a plasma power such as radio frequency (RF) power may be applied to the first plate 41, and the second plate 42 may be grounded. The first plate 41 may be grounded, and the plasma power may be applied to the second plate 42.

The method of manufacturing a thin film according to the present inventive concept may be performed by using the substrate processing apparatus 1.

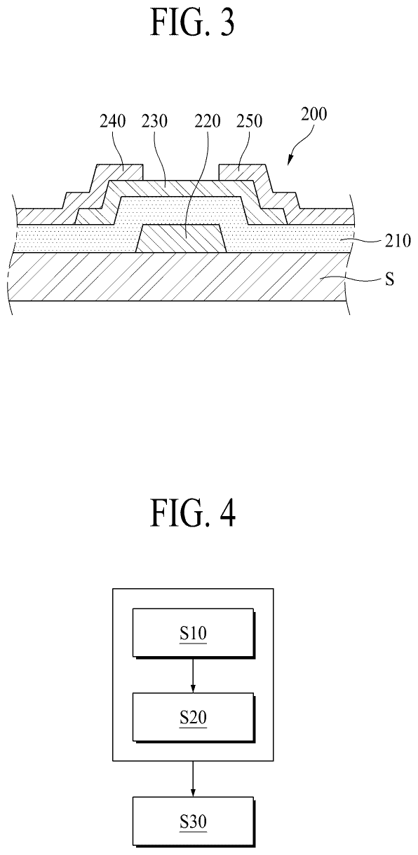

Referring to FIGS. 1 to 4, as illustrated in FIG. 3, the method of manufacturing a thin film according to the present inventive concept may manufacture a thin film implemented as an insulation layer 210 in a thin film transistor (TFT) 200. The insulation layer 210 may be disposed between a gate electrode 220 and a semiconductor layer 230. The gate electrode 220 may be formed on the substrate S. The semiconductor layer 230 may be formed on the insulation layer 210. A source electrode 240 and a drain electrode 250 may be formed on the semiconductor layer 230. When the thin film transistor 200 is manufactured to be more miniaturized and have a thinner thickness, the insulation layer 210 may be thinned, and the leakage of a current may occur due to a tunneling phenomenon as a thickness of the insulation layer 210 is thinned.

To decrease the leakage of a current, the method of manufacturing a thin film according to the present inventive concept is implemented to manufacture a thin film including a high-k dielectric material. Furthermore, the method of manufacturing a thin film according to the present inventive concept is implemented to manufacture a thin film by crystallizing a high-k dielectric material. Accordingly, the method of manufacturing a thin film according to the present inventive concept may manufacture a thin film for more reducing the leakage of a current, thereby contributing to manufacturing the thin film transistor 200 which is finer and has a thinner thickness.

To this end, the method of manufacturing a thin film according to the present inventive concept may include a first formation step S10, a second formation step S20, and a crystallization step S30.

Referring to FIGS. 1 to 5, the first formation step S10 injects a first source gas including a high-k dielectric material to form a first thin film layer 310 on the substrate S. In the first formation step S10, the first source gas may be injected through the first gas flow path 4a included in the injection unit 4. The first source gas may include at least one of hafnium (Hf) and zirconium (Zr). All of hafnium and zirconium correspond to a high-k dielectric material. In a case where the first source gas includes all of hafnium and zirconium, a source gas including hafnium and a source gas including zirconium may be mixed with each other in a buffer tank disposed apart from the injection unit 4 to generate a mixed gas, and then, the mixed gas may be supplied to the injection unit 4 and may be injected into the processing space 100. Therefore, the method of manufacturing a thin film according to the present inventive concept may manufacture a thin film where a step coverage is enhanced, and moreover, may manufacture a thin film where the uniformity of a composition is enhanced.

The first formation step S10 may inject the first source gas to adsorb a high-k dielectric material included in the first source gas onto the substrate S, and then, may inject a first reactant gas to form the first thin film layer 310 on the substrate S. In this case, the first formation step S10 may form the first thin film layer 310 on the substrate S by using an atomic layer deposition (ALD) process. The first reactant gas may react with the first source gas and may be injected through the second gas flow path 4b included in the injection unit 4. For example, the first reactant gas may be ozone (03).

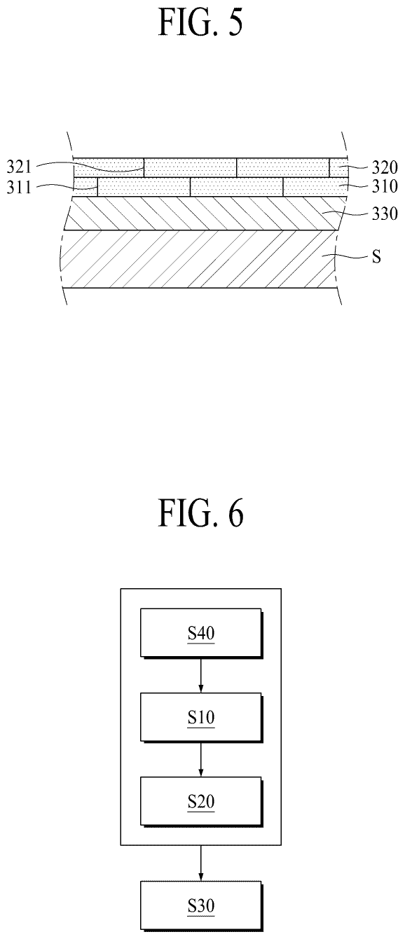

Referring to FIGS. 1 to 5, the second formation step S20 injects a second source gas including a high-k dielectric material to form a second thin film layer 320 on the substrate S. In the second formation step S20, the second source gas may be injected through the first gas flow path 4a included in the injection unit 4. The second source gas may include at least one of hafnium and zirconium. The second formation step S20 may inject the second source gas to adsorb a high-k dielectric material included in the second source gas onto the substrate S, and then, may inject a second reactant gas to form the second thin film layer 320 on the substrate S. In this case, the second formation step S20 may form the second thin film layer 320 on the substrate S by using an atomic layer deposition (ALD) process. The second reactant gas may react with the second source gas and may be injected through the second gas flow path 4b included in the injection unit 4. For example, the second reactant gas may be ozone (O₃). Furthermore, in FIG. 5, the second thin film layer 320 is illustrated as being formed directly on the first thin film layer 310, but is not limited thereto and another thin film layer may be disposed between the second thin film layer 320 and the first thin film layer 310. Also, in FIG. 5, the first thin film layer 310 is illustrated as being formed on a lower film 330 formed on the substrate S, but is not limited thereto and the first thin film layer 310 may be formed directly on the substrate S.

Referring to FIGS. 1 to 5, the crystallization step S30 crystallizes at least one of the first thin film layer 310 and the second thin film layer 320 by using plasma. Because a thin film is manufactured by crystallizing a high-k dielectric material by using plasma through the crystallization step S30, the method of manufacturing a thin film according to the present inventive concept may realize the following effects.

First, a comparative example, which is manufactured as a thin film where all of the first thin film layer 310 and the second thin film layer 320 include a high-k dielectric material and all of the first thin film layer 310 and the second thin film layer 320 are not crystallized, represents a leakage current value which is greater in the same thickness than that of a thin film where all of the first thin film layer 310 and the second thin film layer 320 include a high-k dielectric material and at least one of the first thin film layer 310 and the second thin film layer 320 is crystallized, based on the method of manufacturing a thin film according to the present inventive concept. Therefore, the method of manufacturing a thin film according to the present inventive concept may be implemented to manufacture a thin film where all of the first thin film layer 310 and the second thin film layer 320 include a high-k dielectric material and at least one of the first thin film layer 310 and the second thin film layer 320 is crystallized, and thus, may manufacture a thin film for more decreasing a leakage current despite being formed to have a thickness which is thinner than the thin film according to the comparative example. Therefore, the method of manufacturing a thin film according to the present inventive concept may manufacture the thin film transistor 200 and the like, which are finer and have a thinner thickness and may more decrease the leakage of a current, thereby contributing to more enhancing the performance of the thin film transistor 200 and the like.

Second, in a comparative example which crystallizes a high-k dielectric material through a thermal process, the high-k dielectric material is not crystallized when not formed to have a certain thickness or more. For example, a high-k dielectric material including at least one of hafnium and zirconium may be crystallized only when formed to have a thickness of 100 Å or more, through the thermal process. On the other hand, the method of manufacturing a thin film according to the present inventive concept is implemented to crystallize a high-k dielectric material by using plasma, and thus, may crystallize the high-k dielectric material despite being formed to have a thickness which is thinner than the comparative example which crystallizes the high-k dielectric material through the thermal process. For example, a high-k dielectric material including at least one of hafnium and zirconium may be crystallized only when formed to have a thickness of 60 Å or less, based on plasma. Accordingly, the method of manufacturing a thin film according to the present inventive concept is implemented to crystallize a high-k dielectric material by using plasma, and thus, may manufacture a thin film for more reducing the leakage of a current despite being formed to have a thinner thickness.

The crystallization step S30 may generate plasma by using a plasma gas including at least one of helium (He), argon (Ar), ammonia (NH₃), oxygen (O₂), and hydrogen (H₂). In this case, the first source gas may include at least one of hafnium and zirconium, and the first reactant gas may be ozone (O₃). The first source gas may include at least one of hafnium, zirconium, and aluminum (Al).

Referring to FIGS. 1 to 6, the method of manufacturing a thin film according to the present inventive concept may include a removal step S40.

The removal step S40 removes an oxide film from the lower film 330 formed on the substrate S. The removal step S40 may be performed before the first formation step S10 is performed. Therefore, the first formation step S10 may be performed by forming the first thin film layer 310 on the lower film 330 from which the oxide film is removed through the removal step S40. Therefore, the method of manufacturing a thin film according to the present inventive concept may form the first thin film layer 310 having film quality which is more enhanced. An oxide film formed on the lower film 330 may be exposed to an atmosphere, and due to this, may occur. For example, the oxide film may be formed on the lower film 330 in a process where the substrate S is transferred between process chambers. Undesired pollutants may be removed together through the removal step S40 in a process of removing the oxide film. The removal step S40 may be performed by using an oxide elimination chamber (OEC).

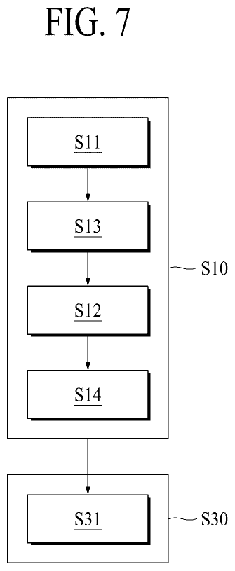

Referring to FIGS. 1 to 7, in the method of manufacturing a thin film according to the present inventive concept, the first formation step S10 may include a first adsorption step S11 and a first deposition step S12.

The first adsorption step S11 injects the first source gas to adsorb the high-k dielectric material onto the substrate S. The first adsorption step S11 may be performed by injecting the first source gas onto the substrate S through the first gas flow path 4a included in the injection unit 4. The source gas may include at least one of hafnium (Hf) and zirconium (Zr). The first adsorption step S11 may inject the first source gas including hafnium or zirconium. The first adsorption step S11 may inject the first source gas including all of hafnium and zirconium. In this case, in the first adsorption step S11, a source gas including hafnium and a source gas including zirconium may be mixed with each other in the buffer tank to generate a mixed gas, and then, the mixed gas may be injected. The first adsorption step S11 may first inject a source gas including one of hafnium and zirconium, and then, may inject a source gas including the other of hafnium and zirconium. The first source gas may include at least one of hafnium, zirconium, and aluminum (Al). For example, the first source gas may be one of HfO₂, ZrO₂, Al₂O₃, and HfZrO.

The first deposition step S12 injects the first reactant gas to deposit a thin film including a high-k dielectric material on the substrate S. The first deposition step S12 may be performed by injecting the first reactant gas onto the substrate S through the second gas flow path 4b included in the injection unit 4. Through the first adsorption step S11 and the first deposition step S12, the first thin film layer 310 may be formed on the substrate S by an atomic layer deposition (ALD) process. The first deposition step S12 may be performed by injecting ozone as the first reactant gas onto the substrate S.

The first formation step S10 may include a first adsorption purge step S13 and a first deposition purge step S14.

The first adsorption purge step S13 may be performed by injecting a purge gas onto the substrate S after the first adsorption step S11 is performed. The first adsorption purge step S13 may be performed by injecting the purge gas onto the substrate S through at least one of the first gas flow path 4a and the second gas flow path 4b of the injection unit 4. The first adsorption purge step S13 may be performed by injecting the purge gas onto the substrate S through a purge gas flow path (not shown) of the injection unit 4. The purge gas flow path, the first gas flow path 4a, and the second gas flow path 4b may be implemented to be spatially apart from one another. After the first adsorption purge step S13 is performed, the first deposition step S12 may be performed.

The first deposition purge step S14 may be performed by injecting the purge gas onto the substrate S after the first deposition step S12 is performed. The first deposition purge step S14 may be performed by injecting the purge gas onto the substrate S through at least one of the first gas flow path 4a and the second gas flow path 4b of the injection unit 4. The first deposition purge step S14 may be performed by injecting the purge gas onto the substrate S through the purge gas flow path (not shown). After the first deposition purge step S14 is performed, the crystallization step S30 may be performed.

Here, the first formation step S10 and the crystallization step S30 may be performed in the processing space 100 having an ultra-vacuum state. For example, the first formation step S10 and the crystallization step S30 may be performed in a state where the processing space 100 has an ultra-vacuum of several mtorr to tens mtorr. Undesired impurities of the first source gas may be more smoothly exhausted in the ultra-vacuum state, and thus, the method of manufacturing a thin film according to the present inventive concept may arrange first source materials included in the first source gas in a uniform lattice structure. Accordingly, the method of manufacturing a thin film according to the present inventive concept may be implemented to be favorable for growing the first source materials, arranged in the uniform lattice structure, as crystallization arrangement having a high-k dielectric constant.

In a case where the first formation step S10 includes the first deposition step S12 and the first adsorption step S11, the crystallization step S30 may include a first crystallization step S31.

The first crystallization step S31 crystallizes the first thin film layer 310. The first crystallization step S31 may be performed after the first deposition step S12 is performed. In this case, the method of manufacturing a thin film according to the present inventive concept may deposit the first thin film layer 310 on the substrate S through the first adsorption step S11 and the first deposition step S12, and then, may crystallize the high-k dielectric material of the first thin film layer 310 by using plasma through the first crystallization step S31. After the first crystallization step S31 is performed, each step may be again performed from the first adsorption step S11. Furthermore, in a case where the first crystallization step S31 is performed after the first deposition step S12 is performed, the method of manufacturing a thin film according to the present inventive concept may perform each step along with the thermal process. The thermal process may be continuously or intermittently performed while the first adsorption step S11, the first deposition step S12, and the first crystallization step S31 are being performed. In a case where the first formation step S10 includes the first deposition purge step S14, the first crystallization step S31 may be performed after the first deposition purge step S14 is performed.

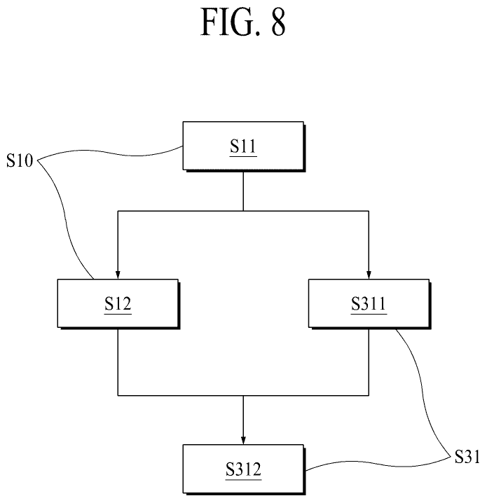

Referring to FIGS. 1 to 8, in the method of manufacturing a thin film according to the present inventive concept, the first deposition step S12 and the first crystallization step S31 may be performed together. In this case, the first reactant gas injected onto the substrate S through the first deposition step S12 may be activated by using plasma generated by the first crystallization step S31 and may reach the substrate S. Accordingly, because the first deposition step S12 and the crystallization step S30 are performed together, the method of manufacturing a thin film according to the present inventive concept may deposit the first thin film layer 310 including a high-k dielectric material onto the substrate S and may crystallize the first thin film layer 310 by using plasma. After the first deposition step S12 and the first crystallization step S31 are performed together, each step may be again performed from the first adsorption step S11. Although not shown, the first deposition step S12 may use oxygen (O2) plasma as the first reactant gas, and thus, may performed deposition and crystallization together.

Referring to FIGS. 1 to 8, in the method of manufacturing a thin film according to the present inventive concept, the first crystallization step S31 may include a first parallel crystallization step S311 and a first subsequent crystallization step S312.

The first parallel crystallization step S311 crystallizes the high-k dielectric material by using plasma. The first parallel crystallization step S311 may be performed along with the first deposition step S12. In this case, the first reactant gas injected onto the substrate S through the first deposition step S12 may be activated by using plasma generated by the first parallel crystallization step S311 and may reach the substrate S. Accordingly, because the first deposition step S12 and the first parallel crystallization step S311 are performed together, the method of manufacturing a thin film according to the present inventive concept may deposit the first thin film layer 310 onto the substrate S and may crystallize the first thin film layer 310 by using plasma.

The first subsequent crystallization step S312 crystallizes the first thin film layer 310 by using plasma. After the first deposition step S12 and the first parallel crystallization step S311 are performed, the first subsequent crystallization step S312 may be performed. Therefore, the method of manufacturing a thin film according to the present inventive concept may be implemented to primarily crystallize the first thin film layer 310 through the first parallel crystallization step S311 and then secondarily crystallize the first thin film layer 310 through the first subsequent crystallization step S312. Therefore, the method of manufacturing a thin film according to the present inventive concept may increase a crystallization rate of the first thin film layer 310, and thus, may manufacture a thin film for more reducing the leakage of a current despite being formed to have a thinner thickness. Accordingly, the method of manufacturing a thin film according to the present inventive concept may contribute to manufacturing the thin film transistor 200 which is finer and has a thinner thickness. After the first subsequent crystallization step S312 is performed, each step may be again performed from the first adsorption step S11.

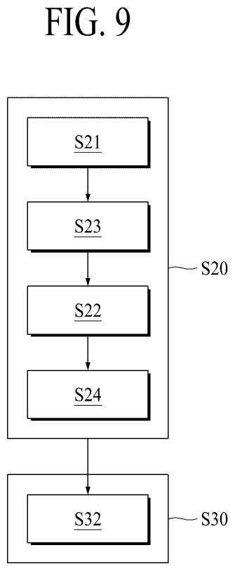

Referring to FIGS. 1 to 9, in the method of manufacturing a thin film according to the present inventive concept, the second formation step S20 may include a second adsorption step S21 and a second deposition step S22.

The second adsorption step S21 injects the second source gas to adsorb the high-k dielectric material onto the substrate S. The second adsorption step S21 may be performed by injecting the second source gas onto the substrate S through the first gas flow path 4a included in the injection unit 4. The second adsorption step S21 may inject the second source gas including hafnium or zirconium. The second adsorption step S21 may inject the second source gas including all of hafnium and zirconium. In this case, in the second adsorption step S21, a source gas including hafnium and a source gas including zirconium may be mixed with each other in the buffer tank to generate a mixed gas, and then, the mixed gas may be injected. The second adsorption step S21 may first inject a source gas including one of hafnium and zirconium, and then, may inject a source gas including the other of hafnium and zirconium. The first source gas may include at least one of hafnium, zirconium, and aluminum (Al). The second source gas may include at least one of hafnium, zirconium, and aluminum (Al). For example, the second source gas may be one of HfO₂, ZrO₂, Al₂O₃, and HfZrO.

The second deposition step S22 injects the second reactant gas to deposit a thin film including a high-k dielectric material on the substrate S. The second deposition step S22 may be performed by injecting the second reactant gas onto the substrate S through the second gas flow path 4b included in the injection unit 4. Through the second adsorption step S21 and the second deposition step S22, the second thin film layer 320 may be formed on the substrate S by an atomic layer deposition (ALD) process. The second deposition step S22 may be performed by injecting ozone as the second reactant gas onto the substrate S.

The second formation step S20 may include a second adsorption purge step S23 and a second deposition purge step S24.

The second adsorption purge step S23 may be performed by injecting a purge gas onto the substrate S after the second adsorption step S21 is performed. The second adsorption purge step S23 may be performed by injecting the purge gas onto the substrate S through at least one of the first gas flow path 4a and the second gas flow path 4b of the injection unit 4. The second adsorption purge step S23 may be performed by injecting the purge gas onto the substrate S through a purge gas flow path (not shown) of the injection unit 4. The purge gas flow path, the first gas flow path 4a, and the second gas flow path 4b may be implemented to be spatially apart from one another. After the second adsorption purge step S23 is performed, the second deposition step S22 may be performed.

The second deposition purge step S24 may be performed by injecting the purge gas onto the substrate S after the second deposition step S22 is performed. The second deposition purge step S24 may be performed by injecting the purge gas onto the substrate S through at least one of the first gas flow path 4a and the second gas flow path 4b of the injection unit 4. The second deposition purge step S24 may be performed by injecting the purge gas onto the substrate S through the purge gas flow path (not shown). After the second deposition purge step S24 is performed, the crystallization step S30 may be performed.

Here, the second formation step S20 and the crystallization step S30 may be performed in the processing space 100 having an ultra-vacuum state. For example, the second formation step S20 and the crystallization step S30 may be performed in a state where the processing space 100 has an ultra-vacuum of several mtorr to tens mtorr. Undesired impurities of the second source gas may be more smoothly exhausted in the ultra-vacuum state, and thus, the method of manufacturing a thin film according to the present inventive concept may arrange second source materials included in the second source gas in a uniform lattice structure. Accordingly, the method of manufacturing a thin film according to the present inventive concept may be implemented to be favorable for growing the second source materials, arranged in the uniform lattice structure, as crystallization arrangement having a high-k dielectric constant.

In a case where the second formation step S20 includes the second deposition step S22 and the second adsorption step S21, the crystallization step S30 may include a second crystallization step S32.

The second crystallization step S32 crystallizes the second thin film layer 320. The second crystallization step S32 may be performed after the second deposition step S22 is performed. In this case, the method of manufacturing a thin film according to the present inventive concept may deposit the second thin film layer 320 on the substrate S through the second adsorption step S21 and the second deposition step S22, and then, may crystallize the high-k dielectric material of the second thin film layer 320 by using plasma through the second crystallization step S32. After the second crystallization step S32 is performed, each step may be again performed from the second adsorption step S21. Furthermore, in a case where the second crystallization step S32 is performed after the second deposition step S22 is performed, the method of manufacturing a thin film according to the present inventive concept may perform each step along with the thermal process. The thermal process may be continuously or intermittently performed while the second adsorption step S21, the second deposition step S22, and the second crystallization step S32 are being performed. In a case where the second formation step S20 includes the second deposition purge step S24, the second crystallization step S32 may be performed after the second deposition purge step S24 is performed.

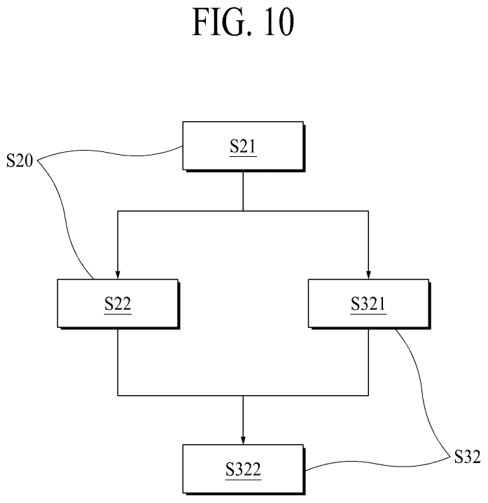

Referring to FIGS. 1 to 10, in the method of manufacturing a thin film according to the present inventive concept, the second deposition step S22 and the second crystallization step S32 may be performed together. In this case, the second reactant gas injected onto the substrate S through the second deposition step S22 may be activated by using plasma generated by the second crystallization step S32 and may reach the substrate S. Accordingly, because the second deposition step S22 and the crystallization step S30 are performed together, the method of manufacturing a thin film according to the present inventive concept may deposit the second thin film layer 320 including a high-k dielectric material onto the substrate S and may crystallize the second thin film layer 320 by using plasma. After the second deposition step S22 and the second crystallization step S32 are performed together, each step may be again performed from the second adsorption step S21. Although not shown, the second deposition step S22 may use oxygen (O₂) plasma as the second reactant gas, and thus, may performed deposition and crystallization together.

Referring to FIGS. 1 to 10, in the method of manufacturing a thin film according to the present inventive concept, the second crystallization step S32 may include a second parallel crystallization step S321 and a second subsequent crystallization step S322.

The second parallel crystallization step S321 crystallizes the high-k dielectric material by using plasma. The second parallel crystallization step S321 may be performed along with the second deposition step S22. In this case, the second reactant gas injected onto the substrate S through the second deposition step S22 may be activated by using plasma generated by the second parallel crystallization step S321 and may reach the substrate S. Accordingly, because the second deposition step S22 and the second parallel crystallization step S321 are performed together, the method of manufacturing a thin film according to the present inventive concept may deposit the second thin film layer 320 onto the substrate S and may crystallize the second thin film layer 320 by using plasma.

The second subsequent crystallization step S322 crystallizes the second thin film layer 320 by using plasma. After the second deposition step S22 and the second parallel crystallization step S321 are performed, the second subsequent crystallization step S322 may be performed. Therefore, the method of manufacturing a thin film according to the present inventive concept may be implemented to primarily crystallize the second thin film layer 320 through the second parallel crystallization step S321 and then secondarily crystallize the second thin film layer 320 through the second subsequent crystallization step S322. Therefore, the method of manufacturing a thin film according to the present inventive concept may increase a crystallization rate of the second thin film layer 320, and thus, may manufacture a thin film for more reducing the leakage of a current despite being formed to have a thinner thickness. Accordingly, the method of manufacturing a thin film according to the present inventive concept may contribute to manufacturing the thin film transistor 200 which is finer and has a thinner thickness. After the second subsequent crystallization step S322 is performed, each step may be again performed from the second adsorption step S21.

Here, when the first thin film layer 310 is crystallized, a first grain boundary 311 (illustrated in FIG. 5) may be formed in the first thin film layer 310. The first grain boundary 311 may be formed to pass through the first thin film layer 310 in a direction in which the first thin film layer 310 is deposited. The first grain boundary 311 may be formed in plurality in the first thin film layer 310. When the second thin film layer 320 is crystallized, a second grain boundary 321 (illustrated in FIG. 5) may be formed in the second thin film layer 320. The second grain boundary 321 may be formed to pass through the second thin film layer 320 in a direction in which the second thin film layer 320 is deposited.

In this case, when the first thin film layer 310 and the second thin film layer 320 are deposited by using the same high-k dielectric material and are crystallized under the same process condition, the first grain boundary 311 and the second grain boundary 321 may be connected with each other. Accordingly, the leakage of a current may occur through the first grain boundary 311 and the second grain boundary 321.

To prevent this, the first source gas and the second source gas may include different high-k dielectric materials. Therefore, in the method of manufacturing a thin film according to the present inventive concept, even when the first thin film layer 310 and the second thin film layer 320 are crystallized under the same process condition, the first grain boundary 311 and the second grain boundary 321 may not be connected with each other. That is, as illustrated in FIG. 5, the first grain boundary 311 and the second grain boundary 321 may be formed at staggered positions. Therefore, the method of manufacturing a thin film according to the present inventive concept may decrease the leakage of a current through the first grain boundary 311 and the second grain boundary 321. In this case, the first formation step S10 and the second formations step S20 may deposit the first thin film layer 310 and the second thin film layer 320 by using the first source gas and the second source gas which differ. Subsequently, in the crystallization step S30, even when the first thin film layer 310 and the second thin film layer 320 are crystallized under the same process condition, the first grain boundary 311 and the second grain boundary 321 may be formed at staggered positions.

Furthermore, the crystallization step S30 may crystallize the first thin film layer 310 and the second thin film layer 320 under different conditions. In this case, even when the first source gas and the second source gas include the same high-k dielectric material, the method of manufacturing a thin film according to the present inventive concept may form the first grain boundary 311 and the second grain boundary 321 at staggered positions, based on a difference between process conditions for crystallization. Accordingly, the method of manufacturing a thin film according to the present inventive concept may decrease the leakage of a current through the first grain boundary 311 and the second grain boundary 321. The crystallization step S30 may crystallize the first thin film layer 310 and the second thin film layer 320 at different crystallization rates, and thus, may form the first grain boundary 311 and the second grain boundary 321 at staggered positions.

Furthermore, the method of manufacturing a thin film according to the present inventive concept may be implemented so that the first source gas and the second source gas include different high-k dielectric materials and the first thin film layer 310 and the second thin film layer 320 are crystallized under different process conditions. Accordingly, a distance by which the first grain boundary 311 and the second grain boundary 321 are staggered with each other may increase, and thus, the method of manufacturing a thin film according to the present inventive concept may more decrease the leakage of a current through the first grain boundary 311 and the second grain boundary 321. For example, the first crystallization step S31 and the second crystallization step S32 may generate plasma by using different plasma gases, and thus, may perform crystallization under different process conditions.

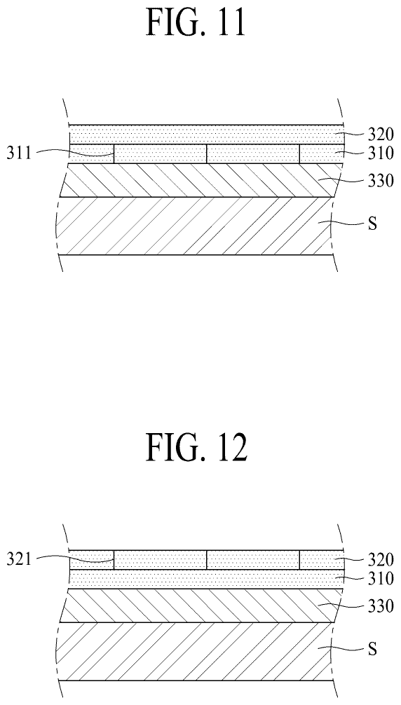

Referring to FIGS. 1 to 12, the method of manufacturing a thin film according to the present inventive concept may be implemented to crystallize only one of the first thin film layer 310 and the second thin film layer 320. For example, the crystallization step S30 may be implemented to crystallize only the first thin film layer 310 and not to crystallize the second thin film layer 320. In this case, as illustrated in FIG. 11, the first grain boundary 311 is formed in only the first thin film layer 310, and the second grain boundary 321 is not formed in the second thin film layer 320. For example, the crystallization step S30 may be implemented to crystallize only the second thin film layer 320 and not to crystallize the first thin film layer 310. In this case, as illustrated in FIG. 12, the second grain boundary 321 is formed in only the second thin film layer 320, and the first grain boundary 311 is not formed in the first thin film layer 310. As described above, the method of manufacturing a thin film according to the present inventive concept may be implemented to crystallize only one of the first thin film layer 310 and the second thin film layer 320, and thus, may prevent the leakage of a current from occurring through a grain boundary.

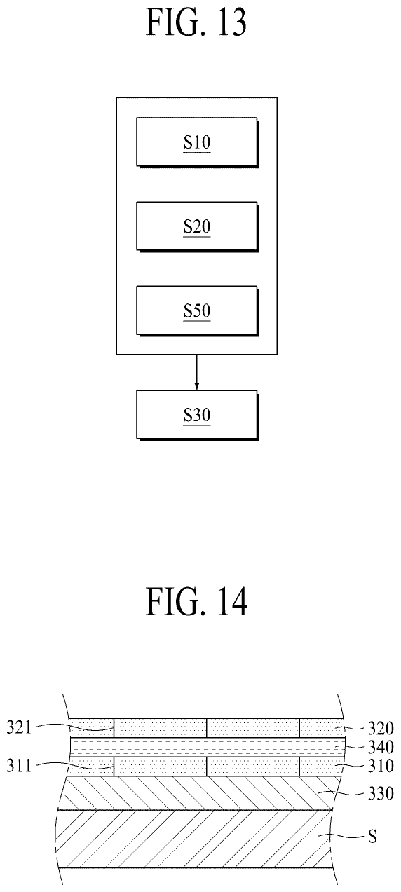

Referring to FIGS. 1 to 14, the method of manufacturing a thin film according to the present inventive concept may include a third crystallization step S50.

The third formation step S50 forms a third thin film layer 340 on the substrate S. The third formation step S50 may form an amorphous third thin film layer 340. Therefore, a grain boundary is not formed in the third thin film layer 340. Accordingly, even when the first source gas is the same as the second source gas and the first thin film layer 310 and the second thin film layer 320 crystallized under the same process condition are formed, the third thin film layer 340 may prevent the occurrence of current leakage through the first grain boundary 311 and the second grain boundary 321. The third formation step S50 may form the third thin film layer 340 which is lower in crystallization rate than each of the first thin film layer 310 and the second thin film layer 320. Therefore, a grain boundary may not be formed in the third thin film layer 340, or fewer grain boundaries than the first thin film layer 310 and the second thin film layer 320 may be formed therein. Accordingly, even when the first source gas is the same as the second source gas and the first thin film layer 310 and the second thin film layer 320 crystallized under the same process condition are formed, the third thin film layer 340 may prevent the occurrence of current leakage through the first grain boundary 311 and the second grain boundary 321.

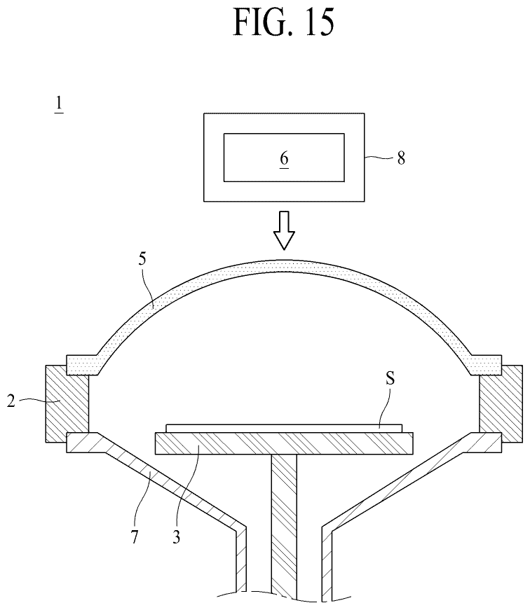

As illustrated in FIG. 14, the third thin film layer 340 may be disposed between the first thin film layer 310 and the second thin film layer 320. In this case, the third formation step S50 may be performed after the first formation step S10 is performed. The second formation step S20 may be performed after the third formation step S50 is performed. Although not shown, the third thin film layer 340 may be disposed between the first thin film layer 310 and the lower film 330. In this case, the first formation step S10 may be performed after the third formation step S50 is performed. The third thin film layer 340 may be disposed on the second thin film layer 320. In this case, the third formation step S50 may be performed after the second formation step S20 is performed. Although not shown, the method of manufacturing a thin film according to the present inventive concept may perform the third formation step S50 a plurality of times, and thus, may form a plurality of third thin film layers 340. In this case, the third thin film layers 340 may be disposed apart from one another. Accordingly, the third thin film layers 340 may prevent the occurrence of current leakage through a grain boundary at different positions.

The third formation step S50 may inject a third source gas to adsorb a third source material of the third source gas onto the substrate S, and then, may inject a third reactant gas to form the third thin film layer 340 on the substrate S. In this case, the third formation step S may form the third thin film layer 340 on the substrate S by using an atomic layer deposition (ALD) process. The third source gas may include a high-k dielectric material, but is not limited thereto and may include a material capable of preventing the leakage of a current through a grain boundary, instead of a high-k dielectric material. The third source gas may be injected through the first gas flow path 4a included in the injection unit 4. The third reactant gas may react with the third source gas and may be injected through the second gas flow path 4b included in the injection unit 4. The third formation step S50 may be performed by injecting the third source gas and the third reactant gas. In this case, the third formation step S50 may form the third thin film layer 340 by using a chemical vapor deposition (CVD) process.

Hereinafter, an embodiment of a thin film according to the present inventive concept will be described in detail.

Referring to FIGS. 1 to 14, a thin film according to the present inventive concept may be manufactured by the method of manufacturing a thin film according to the present inventive concept described above. The thin film according to the present inventive concept may be implemented as the insulation layer 210 disposed between the gate electrode 220 and the semiconductor layer 230, in the thin film transistor 200.

The thin film according to the present inventive concept may include the first thin film layer 310 and the second thin film layer 320.

The first thin film layer 310 may be formed on the substrate S by using a mixed material including a high-k dielectric material. The first thin film layer 310 may be crystallized by plasma. Therefore, the thin film according to the present inventive concept may be implemented to have a dielectric constant capable of decreasing the leakage of a current despite that the first thin film layer 310 is formed to have a thin thickness, thereby contributing to manufacturing the thin film transistor 200 which is finer and has a thinner thickness. The first thin film layer 310 may also be formed on the lower film 330. Although not shown, the thin film according to the present inventive concept may include a plurality of first thin film layers 310. The first thin film layers 310 may be disposed apart from one another.

The first thin film layer 310 may be formed of a mixed material including at least one of hafnium and zirconium. The first thin film layer 310 may be formed of a mixed material including at least one of hafnium, zirconium, and aluminum. The first thin film layer 310 may be deposited on the substrate S through the first formation step S10 and may be crystallized through the crystallization step S30.

The first thin film layer 310 may be formed to have a thickness of 30 Å or less and may be crystallized to have a dielectric constant of 30 K or more. The first thin film layer 310 may be crystallized on a whole surface of a deposition surface, and thus, may be formed to have a thickness of 30 Å or less and a dielectric constant of 30 K or more. Accordingly, the first thin film layer 310 may be implemented to decrease the leakage of a current despite being formed to have a thin thickness.

Furthermore, a dielectric constant of the first thin film layer 310 may be determined based on the following Equation 1.

$$Cox \times ( \frac{D}{A} ) \qquad [ Equation 1 ]$$

In the Equation 1, Cox may be an oxide capacitance of the thin film layer, D may be a thickness of the thin film layer, and A may be an area of the thin film layer. The dielectric constant of the first thin film layer 310 calculated through the Equation 1 may be implemented to 30 K or more.

The first thin film layer 310 may be formed to have an equivalent oxide thickness (EOT) of 6.5 Å or less. EOT represents a certain degree to which a high-k dielectric material shows a thickness effect, compared to silicon dioxide (SiO₂). That is, an EOT denotes a thickness of the high-k dielectric material when having the same capacitance as that of to silicon dioxide (SiO₂). As the first thin film layer 310 is formed to have an EOT of 6.5 Å or less, the first thin film layer 310 may be implemented to have a thin thickness and decrease the leakage of a current.

Referring to FIGS. 1 to 14, the second thin film layer 320 may be formed on the substrate S by using a mixed material including a high-k dielectric material. The second thin film layer 320 may be formed on the first thin film layer 310. Although not shown, the first thin film layer 310 may be formed on the second thin film layer 320. The second thin film layer 320 may be formed of a mixed material including at least one of hafnium and zirconium. The second thin film layer 320 may be formed of a mixed material including at least one of hafnium, zirconium, and aluminum. The second thin film layer 320 may be deposited on the substrate S through the second formation step S20. Although not shown, the thin film according to the present inventive concept may include a plurality of second thin film layers 320. The second thin film layers 320 may be disposed apart from one another.

The second thin film layer 320 may be formed of an amorphous material. In this case, as illustrated in FIG. 11, the first grain boundary 311 is formed in only the first thin film layer 310, and the second grain boundary 321 is not formed in the second thin film layer 320. Accordingly, the method of manufacturing a thin film according to the present disclosure may be implemented to crystallize only the first thin film layer 310, thereby preventing the occurrence of current leakage through a grain boundary.

The second thin film layer 320 may be crystallized by plasma. Accordingly, the thin film according to the present inventive concept may be formed to have a thin thickness and may be implemented to have a dielectric constant capable of decreasing the leakage of a current, thereby contributing to manufacturing the thin film transistor 200 which is finer and has a thinner thickness. The second thin film layer 320 may be crystallized through the crystallization step S30.

The second thin film layer 320 may be crystallized at a crystallization rate which differs from that of the first thin film layer 310. Therefore, the second grain boundary 321 formed in the second thin film layer 320 and the first grain boundary 311 formed in the first thin film layer 310 may be formed at staggered positions, and thus, may not be connected with each other. Therefore, the thin film according to the present inventive concept may decrease the leakage of a current through the first grain boundary 311 and the second grain boundary 321. In this case, the second thin film layer 320 and the first thin film layer 310 may be formed of different high-k dielectric materials. Therefore, even when the second thin film layer 320 and the first thin film layer 310 are crystallized under the same process condition, the second grain boundary 321 and the first grain boundary 311 may be formed at staggered positions. The second thin film layer 320 and the first thin film layer 310 may be crystallized under different process conditions. Accordingly, even when the second thin film layer 320 and the first thin film layer 310 are formed of the same high-k dielectric material, the second grain boundary 321 and the first grain boundary 311 may be formed at staggered positions. The second thin film layer 320 and the first thin film layer 310 may be formed of different high-k dielectric materials and may also be crystallized under different process conditions.

The second thin film layer 320 may be formed to have a thickness of 40 Å or more and 70 Å or less and may be crystallized to have a dielectric constant of 20 K or more and 30 K or less. Here, when the second thin film layer 320 is formed to have a thickness of less than 40 Å, the leakage of a current may increase, and when the second thin film layer 320 is formed to have a thickness of more than 70 Å, thinness is difficult. When the second thin film layer 320 is crystallized to have a dielectric constant of less than 20 K, it is difficult to decrease the leakage of a current, and when the second thin film layer 320 is crystallized to have a dielectric constant of more than 30 K, the second thin film layer 320 has conductivity and is difficult to function as an insulation layer. Based thereon, the thin film according to the present inventive concept may be formed to have a thickness of 40 Å or more and 70 Å or less and may be implemented to have a dielectric constant of 20 K or more and 30 K or less. Furthermore, a dielectric constant of the second thin film layer 320 may be determined based on the Equation 1.

The second thin film layer 320 may be partially crystallized, and thus, may be formed to have a thickness of 40 Å or more and 70 Å or less and may be formed to have a dielectric constant of 20 K or more and 30 K or less. In this case, comparing with that all of the second thin film layer 320 is crystallized, the thin film according to the present inventive concept may be implemented to have a dielectric constant and a thickness sufficient to be used as the insulation layer 210 and reduce a process time, thereby increasing productivity.

The second thin film layer 320 may be formed to have an EOT of 6.5 Å or more and 9.7 Å or less. When an EOT of the second thin film layer 320 is less than 6.5 Å, the leakage of a current increases, and when an EOT of the second thin film layer 320 is more than 9.7 Å, thinness is difficult. Based thereon, the second thin film layer 320 may be formed to have an EOT of 6.5 Å or more and 9.7 Å or less, and thus, may be implemented to decrease the leakage of a current despite being formed to have a thin thickness.

Referring to FIGS. 1 to 14, the thin film according to the present inventive concept may include a third thin film layer 340.

The third thin film layer 340 may be formed on the substrate S by using a mixed material including a high-k dielectric material. The third thin film layer 340 may be formed on the substrate S through the third formation step S50. The third thin film layer 340 may be formed of a mixed material including at least one of hafnium and zirconium. The third thin film layer 340 may be formed of a mixed material including at least one of hafnium, zirconium, and aluminum. As illustrated in FIG. 14, the third thin film layer 340 may be disposed between the first thin film layer 310 and the second thin film layer 320. Although not shown, the third thin film layer 340 may be disposed between the first thin film layer 310 and the lower film 330. The third thin film layer 340 may be formed on the second thin film layer 320. Although not shown, the thin film according to the present inventive concept may include a plurality of third thin film layers 340. The third thin film layers 340 may be disposed apart from one another.

The third thin film layer 340 may be formed of an amorphous material. Therefore, a grain boundary is not formed in the third thin film layer 340. Accordingly, even when the first thin film layer 310 and the second thin film layer 320 are formed by using the same source gas and are crystallized under the same process condition, the third thin film layer 340 may prevent the occurrence of current leakage through the first grain boundary 311 and the second grain boundary 321.

The third thin film layer 340 may be crystallized at a crystallization rate which is lower than that of each of the first thin film layer 310 and the second thin film layer 320. Therefore, a grain boundary is not formed in the third thin film layer 340, or fewer grain boundaries than the first thin film layer 310 and the second thin film layer 320 may be formed. Accordingly, even when the first thin film layer 310 and the second thin film layer 320 are formed by using the same source gas and are crystallized under the same process condition, the third thin film layer 340 may prevent the occurrence of current leakage through the first grain boundary 311 and the second grain boundary 321.

Hereinafter, an embodiment of a substrate processing apparatus according to the present inventive concept will be described in detail with reference to the accompanying drawings.

Referring to FIGS. 1 to 15, the substrate processing apparatus 1 according to the present inventive concept may be implemented to deposit a thin film by using a plasma chemical vapor deposition (PCVD) process and crystallize the thin film. The method of manufacturing a thin film according to the present inventive concept described above may be performed by the substrate processing apparatus 1. The thin film according to the present inventive concept described above may be manufactured by using the substrate processing apparatus 1.

The substrate processing apparatus 1 according to the present inventive concept may include a chamber 2, a susceptor 3, an upper dome 5, and an antenna 6.

The chamber 2 may include a sidewall. The chamber 2 may be formed of a conductor. An internal space of the chamber 2 may have a cylindrical shape. An outer shape of the chamber 2 may be a cuboid shape. The chamber 2 may be cooled by cooling water. The chamber 2, the upper dome 5, and a lower dome 7 may be combined to provide a sealed space. A substrate entrance (not shown) may be provided in a side surface of the chamber 2. The chamber 2 may include an exhaust port (not shown) which is formed in a side surface facing the substrate entrance. The exhaust portion may be connected with a high vacuum pump (not shown). The high vacuum pump may be a turbo molecular pump. The high vacuum pump may maintain a low base pressure and may maintain a pressure of several mtorr or less even in performing a process. An upper surface of the exhaust port may be lower than or equal to an upper surface of the substrate entrance.

The susceptor 3 supports the substrate S. The susceptor 3 may support one substrate S, or may support a plurality of substrates S. In a case where the plurality of substrates S are supported by the susceptor 3, a process of performing a processing process on the plurality of substrates S at a time to manufacture a thin film on each of the substrates S may be performed. The susceptor 3 may be disposed in the chamber 2.

The upper dome 5 covers an upper surface of the chamber 2. The upper dome 5 may be formed of a transparent dielectric material. For example, the upper dome 5 may be formed of quartz or sapphire. The upper dome 5 may be inserted into or coupled to a jaw which is formed on the upper surface of the chamber 2. A coupling portion, coupled to the chamber 2, of the upper dome 5 may be formed in a washer shape for vacuum sealing. The upper dome 5 may also be formed in an arc shape or an oval shape. The upper dome 5 may allow infrared light incident from a lower portion to pass through the upper dome 5. The upper dome 5 may be formed of ceramic which is better in corrosion resistance and anti-corrosion than quartz.

The antenna 6 is disposed over the upper dome 5. The antenna 6 may form inductively-coupled plasma. The antenna 6 may include two one-turn unit antennas. In this case, the two one-turn unit antennas may be disposed to overlap each other on an upper surface and a lower surface. The two one-turn unit antennas may be connected in parallel with an RF power source 140. A width direction of the two one-turn unit antennas may be disposed to vertically stand. In the method of manufacturing a thin film according to the present inventive concept described above, plasma may be generated by the antenna 6. Furthermore, in the method of manufacturing a thin film according to the present inventive concept described above, a source gas and a reactant gas may be injected through an injector (not shown) which is provided to extend long toward the processing space in the upper dome 5 and the lower dome 7. The injector may function as the injection unit described above. The substrate processing apparatus 1 according to the present inventive concept may include a plurality of injectors.

The lower dome 7 may be coupled to the chamber 2 to cover a lower surface of the chamber 2. The lower dome 7 may be formed of a transparent dielectric material. For example, the lower dome 7 may be formed of quartz or sapphire. The lower dome 7 may include a lower dome body having a funnel shape, a washer-shaped coupling portion which is coupled to a jaw formed in the lower surface of the chamber 2, and a cylindrical-shaped cylindrical pipe which is connected with a center of the lower dome body. The lower dome 7 may be inserted into and coupled to the jaw formed in the lower surface of the chamber 2. A coupling portion 158a, coupled to the chamber 2, of the chamber 2 may be formed in a washer shape for vacuum sealing. A driving shape for moving the susceptor 3 may be inserted into and disposed in the cylindrical pipe. A purge gas may be supplied through the lower dome 7. In this case, the purge gas may be supplied through the cylindrical pipe.

The substrate processing apparatus 1 according to the present inventive concept may include an electric wave shield housing 8. The electric wave shield housing 8 may be disposed to surround the antenna 6. The electric wave shield housing 8 may be heated by a heater. Infrared light reflected by the electric wave shield housing 8 may pass through the upper dome 5 and may be incident on the substrate S.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A method of manufacturing a thin film, comprising:
a first formation step of injecting a first source gas including a high-k dielectric material to form a first thin film layer on a substrate;
a second formation step of injecting a second source gas including a high-k dielectric material to form a second thin film layer on the substrate; and
a crystallization step of crystallizing at least one of the first thin film layer and the second thin film layer by using plasma.

2. The method of manufacturing a thin film of claim 1, further comprising a removal step of removing an oxide film from a lower film formed on the substrate before the first formation step is performed,
wherein the first formation step forms the first thin film layer on the lower film from which the oxide film is removed.

3. The method of manufacturing a thin film of claim 1, wherein the first source gas and the second source gas comprise different high-k dielectric materials.

4. The method of manufacturing a thin film of claim 1, wherein the first formation step forms the first thin film layer by using a first source gas including at least one high-k dielectric material of hafnium (Hf) and zirconium (Zr), and
the second formation step forms the second thin film layer by using a second source gas including at least one high-k dielectric material of hafnium (Hf) and zirconium (Zr).

5. The method of manufacturing a thin film of claim 1, wherein the first formation step comprises:
a first adsorption step of injecting the first source gas to adsorb a high-k dielectric material onto the substrate; and
a first deposition step of injecting a first reactant gas reacting with the first source gas to deposit the first thin film layer including a high-k dielectric material on the substrate.

6. The method of manufacturing a thin film of claim 5, wherein the crystallization step comprises a first crystallization step of crystallizing the first thin film layer, and
the first crystallization step is performed after the first deposition step is performed, or is performed along with the first deposition step.

7. The method of manufacturing a thin film of claim 5, wherein the first deposition step performs deposition and crystallization together by using oxygen (O2) plasma as the first reactant gas.

8. The method of manufacturing a thin film of claim 5, wherein the first deposition step injects ozone (O₃) as the first reactant gas.

9. The method of manufacturing a thin film of claim 5, wherein the crystallization step comprises a first crystallization step of crystallizing the first thin film layer, and
the first crystallization step comprises:
a first parallel crystallization step performed along with the first deposition step; and
a first subsequent crystallization step performed after the first deposition step and the first parallel crystallization step are performed.

10. The method of manufacturing a thin film of claim 1, wherein the crystallization step generates plasma by using a plasma gas including at least one of helium (He), argon (Ar), ammonia (NH₃), oxygen (O₂), and hydrogen (H₂).

11. The method of manufacturing a thin film of claim 1, wherein the crystallization step crystallizes the first thin film layer and the second thin film layer at different crystallization rates.

12. The method of manufacturing a thin film of claim 1, wherein the crystallization step crystallizes only the first thin film layer.

13. The method of manufacturing a thin film of claim 1, further comprising a third formation step of forming a third thin film layer on the substrate,
wherein the third formation step forms an amorphous third thin film layer, or forms a third thin film layer which is lower in crystallization rate than each of the first thin film layer and the second thin film layer.

14. A thin film comprising:
a first thin film layer formed on a substrate by using a high-k dielectric material and crystallized by plasma; and
a second thin film layer formed on the substrate by using a high-k dielectric material.

15. The thin film of claim 14, wherein the second thin film layer is crystallized at a crystallization rate which differs from a crystallization rate of the first thin film layer, or is formed of an amorphous material.

16. The thin film of claim 14, wherein the first thin film layer and the second thin film layer are formed by using different high-k dielectric materials.

17. The thin film of claim 14, wherein the first thin film layer is formed by using at least one high-k dielectric material of hafnium (Hf) and zirconium (Zr), and the second thin film layer is formed by using at least one high-k dielectric material of hafnium (Hf) and zirconium (Zr).

18. The thin film of claim 14, further comprising a third thin film layer formed on the substrate, and
the third thin film layer is formed of an amorphous material, or is crystallized at a crystallization rate which is lower than a crystallization rate of each of the first thin film layer and the second thin film layer.

19. A substrate processing apparatus comprising:
a chamber;
a substrate supporting unit supporting a substrate in the chamber;
an upper dome provided on an upper surface of the chamber; and
an antenna disposed over the upper dome to generate inductively-coupled plasma,
wherein the upper dome is formed of ceramic.
